(19) United States
(12) Patent Application Publication
(10) Pub. No.: US 2026/0369961 A1
(43) Pub. Date: Nov. 19, 2026

(54) CLOSED-LOOP OUTPUT-WAVELENGTH TUNING METHOD AND SYSTEM BASED ON NEGATIVE FEEDBACK REGULATION DEVICE

(71) Applicant: HEALTHY PHOTON (NINGBO) TECHNOLOGY CO., LTD, Ningbo (CN)

(72) Inventors: Yin WANG, Ningbo City (CN); Shuai XU, Ningbo City (CN); Ting-Jung LIN, Ningbo City (CN)

(21) Appl. No.: 19/425,795

(22) Filed: Dec. 18, 2025

(30) Foreign Application Priority Data
Dec. 31, 2024 (CN) 202411980797.6

(51) Int. Cl. H01S 5/06; H01S 3/105; H01S 5/00; H01S 5/14

(52) U.S. Cl. CPC H01S 5/0617; H01S 3/105; H01S 5/0014; H01S 5/14

(57) ABSTRACT

A closed-loop output-wavelength tuning method and system is provided for external cavity broadband tunable lasers. The apparatus comprises an external cavity broadband tunable laser (including a galvanometric scanner, a driver, and a resonant cavity) and a negative feedback regulation device (including a visible light laser and a one-dimensional position detector). The method involves establishing a calibration data table correlating light spot position, driver operating voltage, and output laser wavelength. When tuning to a target wavelength, the real-time light spot position is calculated via the negative feedback device, matched with the calibration data to determine the current laser wavelength, and used to iteratively adjust the driver's voltage until stability is achieved at the target wavelength.

### TECHNICAL FIELD

The present invention relates to the field of external cavity broadband tunable lasers, and particularly, to a closed-loop output-wavelength tuning method and system based on a negative feedback regulation device.

### BACKGROUND ART

External cavity broadband tunable lasers operate based on the external cavity principle. Their characteristic is that a laser gain device is placed within an angle-tunable external cavity, and precise tuning of the output wavelength is achieved by adjusting the rotation angle of a galvanometric scanner within the external cavity. However, in practical applications, the rotation angle of the galvanometer mirror is typically controlled by the voltage output from a driver, and factors such as the accuracy of the output voltage, mechanical friction, and aging make it difficult to precisely control the galvanometer mirror's rotation angle. This, in turn, affects the repeatability and accuracy of the output wavelength of the external cavity laser. Here, ‘repeatability’ refers to the consistency of multiple measurement results under the same conditions.

### SUMMARY OF THE INVENTION

To precisely control the rotation angle of the galvanometric scanner and improve the repeatability and accuracy of the output wavelength of the external cavity laser, the present invention proposes a closed-loop output-wavelength tuning method based on a negative feedback regulation device, applied to an external cavity broadband tunable laser;

The external cavity broadband tunable laser comprises: a galvanometric scanner, a galvanometer driver controlling the angle of the galvanometric scanner, and a resonant cavity; the laser wavelength output by the resonant cavity varies in response to changes in the angle of the galvanometric scanner;

The negative feedback regulation device comprises: a visible light laser and a one-dimensional position detector; the visible light laser is configured to emit a laser beam, which is reflected by a galvanometric scanner in the external cavity broadband tuning laser and then directed to the one-dimensional position detector; the closed-loop output wavelength tuning method comprises:

By adjusting the operating voltage of the galvanometer driver, the scanning angle of the galvanometric scanner is varied, thereby altering the position of the light spot formed after reflection of the laser beam emitted by the visible light laser. The laser spot is caused to sequentially pass through a plurality of preset position points on the photosensitive area of the one-dimensional position detector. As the light spot passes each preset position point, recording the position of the point as the light spot position, together with the corresponding galvanometer driver operating voltage, and the laser wavelength output by the resonant cavity at that time, thereby generating calibration data corresponding to that position point, and establishing a calibration data table.

A target laser wavelength to be output by the resonant cavity is set, and a laser wavelength matching the target wavelength is retrieved from the calibration data table. Based on the matched laser wavelength, the corresponding operating voltage of the galvanometer driver is obtained.

The external-cavity broadband-tunable laser is activated, and the galvanometer driver is started with the operating voltage obtained from the matching process so as to rotate the galvanometric scanner, while the negative-feedback regulation device is simultaneously brought into its operating state.

During the operation of the external cavity broadband tunable laser, the real-time spot position is calculated through a negative feedback regulation device, and matched with the spot position in the calibration data table to obtain the corresponding laser wavelength. By comparing this laser wavelength with the target laser wavelength, the voltage adjustment value is determined. The voltage adjustment value is used to increase or decrease the current operating voltage of the galvanometer driver. This process is iteratively executed to make the laser wavelength output by the resonant cavity reach the target laser wavelength. After reaching the target laser wavelength, continuous adjustment is performed to maintain the wavelength stable at the target laser wavelength or within its allowable error range.

Furthermore, the negative feedback regulation device further comprises: a controller; The one-dimensional position detector is used to generate a photocurrent at the irradiated location when the laser spot impinges on its photosensitive area, and the current signal is collected by the electrodes on both ends of the one-dimensional position detector.

The controller calculates the position of the light spot based on the collected current signal; the position of the light spot refers to the vertical distance between the light spot and the center line of the photosensitive area.

Furthermore, said external cavity broadband tunable laser further comprises:

A blazed grating, used for wavelength selection, configured to reflect light of specific wavelengths back into the resonant cavity via diffraction;

The resonant cavity is constituted by a first collimating lens, a laser gain chip, and a second collimating lens. Photons emitted by the laser gain chip pass through the first collimating lens and are reflected by the galvanometric scanner onto the blazed grating. The blazed grating diffracts the incident light according to its wavelength. The diffracted photons are reflected by the galvanometric scanner and directed back through the first collimating lens into the laser gain chip. After wavelength selection by the blazed grating, light of the specific wavelength undergoes gain amplification within the resonant cavity, and when its intensity exceeds the lasing threshold for that wavelength, the laser of the selected specific wavelength is output through the second collimating lens under the selection of the galvanometric scanner and blaze grating.

Furthermore, the laser beam path emitted by the visible light laser and the laser beam path emitted by the laser gain chip do not interfere with each other, ensuring that the beam from one is not obstructed by the optical components of the other.

a laser wavelength matching the target is retrieved from the calibration data table, and the corresponding operating voltage of the galvanometer driver is obtained based on the matched laser wavelength, specifically comprises:

The calibration data table is searched for a laser wavelength matching the target; if a matching laser wavelength exists, the corresponding operating voltage of the galvanometer driver is obtained. If no matching laser wavelength exists, interpolation is performed on the calibration data table to obtain calibration data corresponding to the target laser wavelength.

The corresponding laser wavelength is obtained by matching the real-time spot position with the spot positions in the calibration data table, specifically comprises: the real-time spot position is matched with the spot positions in the calibration data table; if a matching spot position exists, the laser wavelength corresponding to that spot position is obtained. If no matching spot position exists, interpolation is performed on the calibration data table to obtain calibration data corresponding to the real-time spot position, and the laser wavelength contained in the calibration data is then acquired.

Furthermore, the interpolation of the calibration data table to obtain calibration data matching the target laser wavelength is performed, specifically comprises: Finding the two laser wavelengths in the calibration data table closest to the target laser wavelength and their corresponding calibration data;

Calculating the calibration data matching the target laser wavelength based on the closest calibration data; said calculation formulas include:

$$V = {V}_{1} + \frac{( {V}_{2} - {V}_{1} ) \times ( λ - {λ}_{1} )}{( {λ}_{2} - {λ}_{1} )} ;$$

$$x = {x}_{1} + \frac{( {x}_{2} - {x}_{1} ) \times ( λ - {λ}_{1} )}{( {λ}_{2} - {λ}_{1} )} ;$$

Where, V₁, V₂ represent the operating voltages of the galvanometer driver in the closest calibration data; λ₁, λ₂ represent the laser wavelengths corresponding to V₁, V₂ respectively in the closest calibration data; x₁, x₂ represent the light spot positions corresponding to V₁, V₂ respectively in the closest calibration data; A represents the target laser wavelength; wherein: V₁<V<V₂; V,x represent the operating voltage of the galvanometer driver and light spot position matching the target laser wavelength, respectively.

Furthermore, the controller calculates the spot position based on the collected current signal, with the calculation formula as follows:

$${I}_{L} = \frac{1}{2} ( 1 + \frac{2}{L} x ) {I}_{0}$$

$${I}_{R} = \frac{1}{2} ( 1 - \frac{2}{L} x ) {I}_{0} ;$$

$$x = \frac{Δ}{2 \sum } L ; Δ = {I}_{L} - {I}_{R} ; \sum = {I}_{L} + {I}_{R} ;$$

Where, I₀ is the magnitude of the photocurrent produced when the laser spot impinges on the photosensitive area; I_{L} and I_{R} represent the photocurrents received by the first and second electrodes of the one-dimensional position detector, respectively; L represents the length of the photosensitive area of the one-dimensional position detector; x represents the calculated light spot position.

An embodiment of the present invention also provides a closed-loop output-wavelength tuning system based on a negative feedback regulation device, applied to an external cavity broadband tunable laser;

The external cavity broadband tunable laser comprises: a galvanometric scanner, a galvanometer driver controlling the angle of the galvanometric scanner, and a resonant cavity; the laser wavelength output by the resonant cavity varies in response to changes in the angle of the galvanometric scanner;

The negative feedback regulation device comprises: a visible light laser and a one-dimensional position detector; the visible light laser is configured to emit a laser beam, which is reflected by a galvanometric scanner in the external cavity broadband tuning laser and then directed to the one-dimensional position detector; the closed-loop output wavelength tuning system comprises:

A calibration module, configured to adjust the operating voltage of the galvanometer driver so as to vary the scanning angle of the galvanometric scanner, thereby altering the position of the light spot formed after reflection of the laser beam emitted by the visible light laser, causing the light spot to sequentially pass through a plurality of preset position points on the photosensitive area of the one-dimensional position detector. As the light spot passes each preset position point, recording the position of the point as the light spot position, together with the corresponding galvanometer driver operating voltage, and the laser wavelength output by the resonant cavity at that time, thereby generating calibration data corresponding to that position point, and establishing a calibration data table.

A matching module, configured to set a target laser wavelength to be output by the resonant cavity, and a laser wavelength matching the target wavelength is retrieved from the calibration data table. Based on the matched laser wavelength, the corresponding operating voltage of the galvanometer driver is obtained.

A startup module, configured to start the external cavity broadband tunable laser, and the galvanometer driver is started with the operating voltage obtained from the matching process so as to rotate the galvanometric scanner, while the negative-feedback regulation device is simultaneously brought into its operating state.

A closed-loop regulation module, configured to, during operation of the external cavity broadband tunable laser, calculate a real-time light spot position through the negative feedback regulation device, and match with the spot position in the calibration data table to obtain the corresponding laser wavelength. By comparing this laser wavelength with the target laser wavelength, the voltage adjustment value is determined. The voltage adjustment value is used to increase or decrease the current operating voltage of the galvanometer driver. This process is iteratively executed to make the laser wavelength output by the resonant cavity reach the target laser wavelength. After reaching the target laser wavelength, continuous adjustment is performed to maintain the wavelength stable at the target laser wavelength or within its allowable error range.

Furthermore, said negative feedback regulation device further comprises: a controller; The one-dimensional position detector is used to generate a photocurrent at the irradiated location when the laser spot impinges on its photosensitive area, and the current signal is collected by the electrodes on both ends of the one-dimensional position detector.

The controller calculates the position of the light spot based on the collected current signal; the position of the light spot refers to the vertical distance between the light spot and the center line of the photosensitive area.

Furthermore, said external cavity broadband tunable laser further comprises:

A blazed grating, used for wavelength selection, configured to reflect light of specific wavelengths back into the resonant cavity via diffraction;

The resonant cavity is constituted by a first collimating lens, a laser gain chip, and a second collimating lens. Photons emitted by the laser gain chip pass through the first collimating lens and are reflected by the galvanometric scanner onto the blazed grating. The blazed grating diffracts the incident light according to its wavelength. The diffracted photons are reflected by the galvanometric scanner and directed back through the first collimating lens into the laser gain chip. After wavelength selection by the blazed grating, light of the specific wavelength undergoes gain amplification within the resonant cavity, and when its intensity exceeds the lasing threshold for that wavelength, the laser of the selected specific wavelength is output through the second collimating lens under the selection of the galvanometric scanner and blaze grating.

Compared with the prior art, the present invention at least contains the following beneficial effects:
(1) The present invention adjusts the operating voltage of the galvanometer driver to cause the light spot formed by the laser beam from the visible light laser to sequentially pass through a plurality of preset position points on the photosensitive area of the one-dimensional position detector. As the light spot passes each preset position point, recording the position of the point as the light spot position, together with the corresponding galvanometer driver operating voltage, and the laser wavelength output by the resonant cavity at that time, thereby generating calibration data corresponding to that position point, and establishing a calibration data table. During the operation of the external cavity broadband tunable laser, the real-time spot position is calculated through a negative feedback regulation device, and matched with the spot position in the calibration data table to obtain the corresponding laser wavelength. By comparing this laser wavelength with the target laser wavelength, the voltage adjustment value is determined. The voltage adjustment value is used to increase or decrease the current operating voltage of the galvanometer driver. This process is iteratively executed to make the laser wavelength output by the resonant cavity reach the target laser wavelength. After reaching the target laser wavelength, continuous adjustment is performed to maintain the wavelength stable at the target laser wavelength or within its allowable error range. This achieves precise control of the rotation angle of the galvanometric scanner, thereby improving the repeatability and accuracy of the output wavelength.
(2) By employing the negative feedback regulation device, the present invention can monitor and adjust the laser wavelength in real time, significantly improving the precision of wavelength regulation. The calibration data table ensures the correspondence between the operating voltage of the galvanometer driver and the actual laser wavelength, thereby achieving precise control of the output wavelength;
(3) Through the closed-loop regulation mechanism, the present invention can continuously monitor the real-time light spot position and dynamically adjust the operating voltage of the galvanometer driver based on actual measurements, ensuring the output wavelength remains stable near the target laser wavelength, improving the overall stability of the system;
(4) Through the automated tuning mechanism, the present invention simplifies the operation process, reduces the need for manual intervention, lowers operational difficulty and error rate. Users only need to set the target laser wavelength, and the system can automatically complete the tuning process;
(5) Through the closed-loop tuning module, the present invention can promptly detect and correct wavelength deviations, improving system reliability and robustness. Even in the presence of factors such as inaccuracies in the output voltage of the galvanometer driver and mechanical friction, the system can maintain the accuracy of the output wavelength.

### BRIEF DESCRIPTION OF THE DRAWINGS

FIG. 1 is an overall structural diagram of the external cavity broadband tunable laser and the negative feedback regulation device;

FIG. 2 is a structural diagram of a closed-loop output-wavelength tuning system based on a negative feedback regulation device;

FIG. 3 is a schematic diagram illustrating the operating principle of a one-dimensional position detector;

FIG. 4 is a schematic diagram illustrating the relationship between the galvanometric scanner's rotation angle and the laser light spot position.

### IN THE FIGURES

1. Blazed grating; 2. Galvanometric scanner; 3. Galvanometer driver; 4. First collimating lens; 5. Infrared laser chip; 6. Second collimating lens; 7. Visible light laser; 8. One-dimensional position detector; 9. Controller.

### DETAILED DESCRIPTION OF THE EMBODIMENTS

The following are specific embodiments of the present invention combined with the accompanying drawings, providing further description of the technical solutions of the present invention. However, the present invention is not limited to these embodiments.

### Embodiment 1

The output wavelength of an external cavity laser has a positive correlation with the rotation angle of the galvanometric scanner. The rotation angle of the galvanometric scanner is controlled by the galvanometer driver; applying voltages of different magnitudes changes the rotation angle of the galvanometer mirror. However, due to factors such as the inaccuracy of the galvanometer driver voltage, the rotation angle of the galvanometric scanner may vary even at the same voltage level. This limitation leads to an output wavelength error of up to +3 nm, which is unacceptable for certain high-precision spectrometers. To address the low repeatability of the galvanometric scanner's rotation angle, the present invention proposes a closed-loop output wavelength tuning method based on a negative feedback regulation device, applied to an external cavity broadband tunable laser;

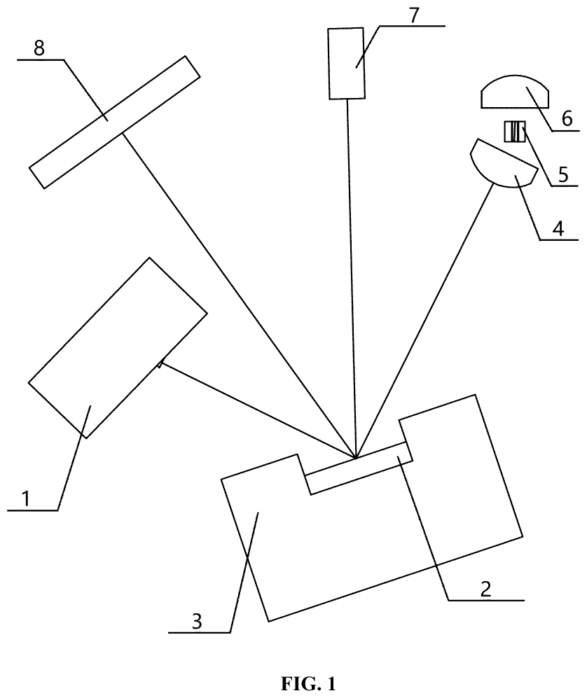

As shown in FIG. 1, the external cavity broadband tunable laser comprises a galvanometric scanner 2, a galvanometer driver 3 for controlling the angle of the galvanometric scanner and a resonant cavity. The output laser wavelength of the resonant cavity varies based on changes in the angle (rotation angle) of the galvanometric scanner.

### Said External Cavity Broadband Tunable Laser Further Comprises:

A blazed grating 1, used for wavelength selection, configured to reflect light of specific wavelengths back into the resonant cavity via diffraction; Said resonant cavity is constituted by a first collimating lens 4, a laser gain chip 5, and a second collimating lens 6. Photons emitted from the laser gain chip 5 pass through the first collimating lens 4 and are reflected by the galvanometer mirror 2 onto the blazed grating 1. The blazed grating 1 diffracts the incident light according to its wavelength. The diffracted photons are reflected by the galvanometer mirror 2 and directed back through the first collimating lens 4 into the laser gain chip 5. After wavelength selection by the blazed grating 1, light of a specific wavelength undergoes gain amplification within the resonant cavity; when its intensity exceeds the lasing threshold for that wavelength, the laser of the selected wavelength is output through the second collimating lens 6 under the selection of the galvanometric scanner 2 and blaze grating 1. The second collimating lens 6 not only reflects part of the light back into the resonant cavity, but also serves as the emission end of the entire external cavity broadband tunable laser, emitting the laser whose power exceeds the lasing threshold.

The negative feedback regulation device comprises a visible light laser 7 and a one-dimensional position detector 8. The visible light laser 7 is configured to emit a laser beam, which is reflected by the galvanometric scanner 2 in the external cavity broadband tunable laser onto the one-dimensional position detector 8. The negative feedback regulation device further comprises a controller 9;

In this embodiment, the one-dimensional position detector 8 is a one-dimensional linear position detector (PSD) with a photosensitive surface size of 1 mm*12 mm and a position resolution of 0.3 μm.

The one-dimensional position detector 8 is configured to generate a photocurrent at the location where the laser spot impinges on its photosensitive region, and the current signal is collected by electrodes at both ends of the one-dimensional position detector 8; The controller 9 calculates the light spot position based on the collected current signals. The light spot position is defined as the vertical distance from the center point of the light spot to the center line of the photosensitive area.

It should be noted that a one-dimensional PSD is a type of photodetector widely used to measure parameters such as displacement, angular variation, and vibration. In laser reflection-based measurement systems, a PSD can provide precise position signals by detecting changes in the position of a laser spot. In the present invention, a PSD is used to detect the displacement of the laser spot in a single direction. The surface of the PSD is typically made of a uniformly distributed resistive material. When a laser spot irradiates its surface, a photocurrent is produced at the illuminated location and signals are collected by two electrodes. Depending on the position of the laser spot on the resistive surface, the current is distributed to the two electrodes in different proportions. By measuring the current difference between the two ends, the position of the light spot can be determined.

As shown in FIG. 3, with the center of the photosensitive region set as the coordinate origin, the position of the laser spot on the photosensitive area, i.e., the light spot position, is x. The controller 9 calculates the spot position based on the collected current signal according to the following formula:

$${I}_{L} = \frac{1}{2} ( 1 + \frac{2}{L} x ) {I}_{0}$$

$${I}_{R} = \frac{1}{2} ( 1 - \frac{2}{L} x ) {I}_{0} ;$$

$$x = \frac{Δ}{2 \sum } L ; Δ = {I}_{L} - {I}_{R} ; \sum = {I}_{L} + {I}_{R} ;$$

Where, I₀ is the magnitude of the photocurrent produced when the laser spot impinges on the photosensitive area; I_{L} and I_{R} represent the photocurrents received by the first and second electrodes of the one-dimensional position detector 8, respectively; L represents the length of the photosensitive area of the one-dimensional position detector 8; x represents the calculated light spot position.

It should be noted that the photocurrent output from the electrodes at both ends of the one-dimensional position detector are also converted into voltage signals via resistors. When the galvanometer driver changes the rotation angle of the galvanometric scanner (the scanner angle is based on the rotation angle relative to an initial or reference position), the position of the light spot from the visible light laser on the photosensitive area shifts accordingly. Consequently, voltage signals output by the electrodes at both ends of the one-dimensional position detector also change. After passing through a data processing circuit board, these two signals are converted into voltage values representing the actual position of the light spot on the photosensitive area (with the center of the photosensitive area as the origin). In the present invention, every 0.5 V output voltage corresponds to 1 mm of laser spot displacement, with the polarity indicating the direction of the spot.

The laser beam path emitted by the visible light laser 7 and the laser beam path emitted by the infrared laser chip 5 do not interfere with each other, ensuring that the beam from one is not obstructed by the optical components of the other.

### The Closed-Loop Output-Wavelength Tuning Method Comprises:

By adjusting the operating voltage of the galvanometer driver, the scanning angle of the galvanometric scanner is varied, thereby altering the position of the light spot formed after reflection of the laser beam emitted by the visible light laser 7. The laser spot is caused to sequentially pass through a plurality of preset position points on the photosensitive area of the one-dimensional position detector 8. As the light spot passes each preset position point, recording the position of the point as the light spot position, together with the corresponding galvanometer driver operating voltage, and the laser wavelength output by the resonant cavity at that time, thereby generating calibration data corresponding to that position point, and establishing a calibration data table.

A target laser wavelength to be output by the resonant cavity is set, and a laser wavelength matching the target wavelength is retrieved from the calibration data table. Based on the matched laser wavelength, the corresponding operating voltage of the galvanometer driver is obtained.

Retrieving a laser wavelength matching the target from the calibration data table, and the corresponding operating voltage of the galvanometer driver is obtained based on the matched laser wavelength, specifically comprises:

The calibration data table is searched for a laser wavelength matching the target; if a matching laser wavelength exists, the corresponding operating voltage of the galvanometer driver is obtained. If no matching laser wavelength exists, interpolation is performed on the calibration data table to obtain calibration data corresponding to the target laser wavelength. Performing interpolation on the calibration data table to obtain calibration data corresponding to the target laser wavelength, specifically comprises:

Finding the two laser wavelengths in the calibration data table closest to the target laser wavelength and their corresponding calibration data;

Calculating the calibration data matching the target laser wavelength based on the closest calibration data; the calculation formulas include:

$$V = {V}_{1} + \frac{( {V}_{2} - {V}_{1} ) \times ( λ - {λ}_{1} )}{( {λ}_{2} - {λ}_{1} )} ;$$

$$x = {x}_{1} + \frac{( {x}_{2} - {x}_{1} ) \times ( λ - {λ}_{1} )}{( {λ}_{2} - {λ}_{1} )} ;$$

Where, V₁, V₂ represent the operating voltages of the galvanometer driver in the closest calibration data; λ₁, λ₂ represent the laser wavelengths corresponding to V₁, V₂ respectively in the closest calibration data; x₁, x₂ represent the light spot positions corresponding to V₁, V₂ respectively in the closest calibration data; A represents the target laser wavelength; wherein: V₁<V<V₂; V,x represent the operating voltage of the galvanometer driver and light spot position matching the target laser wavelength, respectively.

The external-cavity broadband-tunable laser is activated, and the galvanometer driver is started with the operating voltage obtained from the matching process so as to rotate the galvanometric scanner 2, while the negative-feedback regulation device is simultaneously brought into its operating state.

During the operation of the external cavity broadband tunable laser, the real-time spot position is calculated through a negative feedback regulation device, and matched with the spot position in the calibration data table to obtain the corresponding laser wavelength. By comparing this laser wavelength with the target laser wavelength, the voltage adjustment value is determined. The voltage adjustment value is used to increase or decrease the current operating voltage of the galvanometer driver. This process is iteratively executed to make the laser wavelength output by the resonant cavity reach the target laser wavelength. After reaching the target laser wavelength, continuous adjustment is performed to maintain the wavelength stable at the target laser wavelength or within its allowable error range.

Additionally, it should be noted that in this embodiment:
Changes in the operating voltage of the galvanometer driver result in a change in the rotation direction of the galvanometric scanner. Specifically:
Increase in galvanometer driver operating voltage: The galvanometer mirror rotates in one direction.
Decrease in galvanometer driver operating voltage: The galvanometer mirror rotates in the opposite direction.

This relationship is based on the fundamental principle by which the galvanometer driver controls the galvanometric scanner. An increase or decrease in the galvanometer driver operating voltage alters the electromagnetic torque applied to the galvanometric scanner, causing the scanner to rotate in a specific direction.

This embodiment sets a minimum value for voltage change, referred to as the voltage adjustment value. When the laser wavelength is longer than the target wavelength, the voltage adjustment value is set to a negative value, and the current operating voltage of the galvanometer driver is decreased according to this negative voltage adjustment value, causing the galvanometric scanner 2 to rotate in the opposite direction. When the laser wavelength is shorter than the target laser wavelength, the voltage adjustment value is set to a positive value, and the current operating voltage of the galvanometer driver is increased according to this positive voltage adjustment value, causing the galvanometric scanner 2 to rotate in the other direction.

Matching the real-time light spot position with the light spot positions in the calibration data table to obtain the corresponding laser wavelength. Specifically, if a matching spot position exists, the laser wavelength corresponding to that spot position is obtained. If no matching spot position exists, interpolation is performed on the calibration data table to obtain calibration data corresponding to the real-time spot position, and the laser wavelength contained in the calibration data is then acquired.

In this embodiment, interpolation is performed on the calibration data table to obtain calibration data corresponding to the real-time spot position. This interpolation method is the same as that described above for obtaining calibration data corresponding to the target laser wavelength, except that here it calculates the corresponding laser wavelength and the operating voltage of the galvanometer driver.

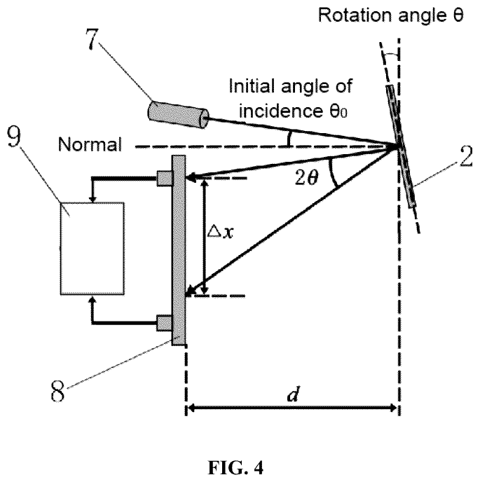

As shown in FIG. 4, since a certain mathematical relationship exists between the galvanometric scanner rotation angle and the laser light spot position, and the output laser wavelength of the resonant cavity varies with changes in the scanner angle, in the structure of the external cavity broadband tunable laser combined with the negative feedback regulation device, utilizes the galvanometric scanner shared within the external cavity. By monitoring the changes in the laser spot position on the photosensitive region of the one-dimensional position detector caused by the rotation of the scanner angle, closed-loop precise control of the output laser wavelength of the resonant cavity can be achieved.

### Two Aspects Need Detailed Explanation Here:

1. A certain mathematical relationship exists between the rotation angle of the galvanometric scanner and the laser spot position.

As shown in FIG. 4: When measuring the rotation angle of the galvanometric scanner 2 using the one-dimensional position detector 8, the beam emitted by the visible light laser 7 obliquely impinges on the galvanometric scanner 2, and the reflected beam from the scanner is incident on the photosensitive area of the one-dimensional position detector 8. When the galvanometric scanner 2 rotates, the position of the light spot of the reflected beam on the photosensitive area shifts correspondingly. Let the incident angle of the beam emitted by the visible light laser 7 be θ₀, the rotation angle of the galvanometric scanner 2 be θ, the displacement Δx of the laser light spot on the photosensitive area and the rotation angle θ of the galvanometer mirror 2 satisfy the following mathematical relationship:

Δx=d*tan(2θ);

Where d is the vertical distance from the laser incidence point on the galvanometric scanner 2 to the PSD. When the galvanometric scanner 2 undergoes small-angle rotation, tan (2θ) is approximately equal to 2θ, therefore the displacement of the laser light spot is approximately linearly related to the rotation angle of the galvanometric scanner 2. By measuring the position change of the laser spot on the PSD and combining it with the known optical path distance d, the rotation angle of the galvanometric scanner 2 can be accurately calculated.

2. The laser wavelength output by the resonant cavity varies based on changes in the rotation angle of the galvanometric scanner 2:

An external cavity broadband tunable laser positions the laser gain device in a tunable external cavity and achieves precise tuning of the output wavelength by adjusting optical elements (such as a grating or galvanometer mirror) within the external cavity. In this embodiment, the output laser wavelength is tuned by rotating the galvanometric scanner 2 within the external cavity. The blazed grating 1 reflects light of different wavelengths back into the resonant cavity at different angles.

When the external cavity length is adjusted by rotating or translating the galvanometric scanner 2, it changes the light path, thereby altering the effective length of the optical cavity. Assuming the rotation angle of the galvanometer mirror 2 is 0, the optical path distance from the galvanometric scanner 2 to the blazed grating 1 is D. For small angles, the optical path change ΔF is approximately:

ΔF=F2−F1≈2D·sin(θ);

Where, F1 represents the optical path distance from the galvanometer mirror incidence point to the first collimating lens 4, F2 represents the length of the resonant cavity;

The mode wavelength κ of the optical cavity (i.e., the external cavity) is related to the optical cavity length F, generally expressed as: κ=2 F/m;

Where m is the order of the mode (a positive integer), and the optical cavity length F=F1+F2+D;

It should be explained that the mode wavelength of the optical cavity refers to the specific wavelengths allowed to exist within the resonant cavity. Through a preset gain curve, specific wavelengths are selected and allowed to compete. Finally, the wavelength with the strongest light intensity is retained and emitted as the output wavelength.

When the galvanometric scanner 2 rotates, the angle of incidence θ₀ changes. According to the above formula κ=2 F/m, the output laser wavelength λ also changes accordingly. The change in wavelength is:

$$Δλ = {λ}^{′} - λ = \frac{2 D \cdot θ}{m}$$

Where, λ′ represents the laser wavelength output by the resonant cavity after the change in the rotation angle of the galvanometric scanner 2; A represents the laser wavelength output by the resonant cavity before the change in rotation angle;

Thus, it can be seen that for small angle changes, the variation of output laser wavelength λ is approximately linearly related to the rotation angle θ of the galvanometric scanner 2. By controlling the rotation angle of the galvanometric scanner 2, continuous tuning of the laser output wavelength can be achieved, covering a relatively wide wavelength range.

From the detailed explanation of the above two aspects, it can be understood that: by sharing the galvanometric scanner within the external cavity broadband tunable laser, the rotation of the scanner angle causes a change in the laser spot position on the photosensitive region of the one-dimensional position detector, thereby enabling closed-loop precise control of the output laser wavelength of the resonant cavity.

In the present invention, by adjusting the operating voltage of the galvanometer driver, the laser beam emitted by the visible-light laser is made to sequentially pass through multiple preset positions on the photosensitive region of the one-dimensional position detector. When the laser spot passes each preset position, the position of the spot (i.e., the spot position), the corresponding operating voltage of the galvanometer driver, and the output laser wavelength of the resonant cavity at that moment are recorded to form the calibration data corresponding to that position, and a calibration data table is established. During operation of the external cavity broadband tunable laser, calculates the real-time light spot position via the negative feedback regulation device, and by matching the real-time spot position with the spot positions in the calibration data table, the corresponding laser wavelength is obtained. By comparing this wavelength with the target laser wavelength, a voltage adjustment value is determined, which is then used to increase or decrease the current galvanometer driver operating voltage. This process is repeated until the output laser wavelength of the resonant cavity stabilizes at the target wavelength or within an allowable error range, thereby achieving precise control of the galvanometer rotation angle and improving the repeatability and accuracy of the output wavelength.

### Embodiment 2

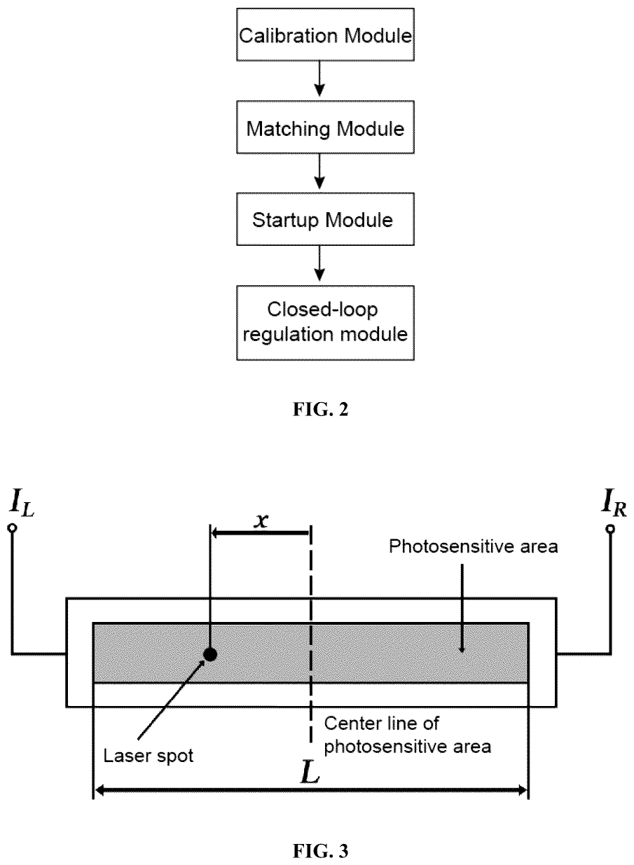

As shown in FIG. 2, the present invention also proposes a closed-loop output-wavelength tuning system based on a negative feedback regulation device, applied to an external cavity broadband tunable laser;

The external cavity broadband tunable laser comprises: a galvanometric scanner, a galvanometer driver controlling the angle of the galvanometer mirror, and a resonant cavity.

The output laser wavelength of the resonant cavity varies based on changes in the scanner angle;

The external cavity broadband tunable laser further comprises:

A blazed grating, used for wavelength selection, configured to reflect light of specific wavelengths back into the resonant cavity via diffraction;

The resonant cavity is constituted by a first collimating lens, a laser gain chip, and a second collimating lens. Photons emitted by the laser gain chip pass through the first collimating lens and are reflected by the galvanometric scanner onto the blazed grating. The blazed grating diffracts the incident light according to its wavelength. The diffracted photons are reflected by the galvanometric scanner and directed back through the first collimating lens into the laser gain chip. After wavelength selection by the blazed grating, light of the specific wavelength undergoes gain amplification within the resonant cavity, and when its intensity exceeds the lasing threshold for that wavelength, the laser of the selected specific wavelength is output through the second collimating lens under the selection of the galvanometric scanner and blaze grating.

The negative feedback regulation device comprises: a visible light laser and a one-dimensional position detector; the visible light laser is configured to emit a laser beam, which is reflected by a galvanometric scanner in the external cavity broadband tuning laser and then directed to the one-dimensional position detector. The negative feedback regulation device further comprises: a controller;

The one-dimensional position detector is used to generate a photocurrent at the irradiated location when the laser spot impinges on its photosensitive area, and the current signal is collected by the electrodes on both ends of the one-dimensional position detector.

The controller calculates the position of the light spot based on the collected current signal; the position of the light spot refers to the vertical distance between the light spot and the center line of the photosensitive area.

The closed-loop output wavelength tuning system comprises:

A calibration module, configured to adjust the operating voltage of the galvanometer driver so as to vary the scanning angle of the galvanometric scanner, thereby altering the position of the light spot formed after reflection of the laser beam emitted by the visible light laser, causing the light spot to sequentially pass through a plurality of preset position points on the photosensitive area of the one-dimensional position detector. As the light spot passes each preset position point, recording the position of the point as the light spot position, together with the corresponding galvanometer driver operating voltage, and the laser wavelength output by the resonant cavity at that time, thereby generating calibration data corresponding to that position point, and establishing a calibration data table.

A matching module, configured to set a target laser wavelength to be output by the resonant cavity, and a laser wavelength matching the target wavelength is retrieved from the calibration data table. Based on the matched laser wavelength, the corresponding operating voltage of the galvanometer driver is obtained.

A startup module, configured to start the external cavity broadband tunable laser, and the galvanometer driver is started with the operating voltage obtained from the matching process so as to rotate the galvanometric scanner, while the negative-feedback regulation device is simultaneously brought into its operating state.

A closed-loop regulation module, configured to, during operation of the external cavity broadband tunable laser, calculate a real-time light spot position through the negative feedback regulation device, and match with the spot position in the calibration data table to obtain the corresponding laser wavelength. By comparing this laser wavelength with the target laser wavelength, the voltage adjustment value is determined. The voltage adjustment value is used to increase or decrease the current operating voltage of the galvanometer driver. This process is iteratively executed to make the laser wavelength output by the resonant cavity reach the target laser wavelength. After reaching the target laser wavelength, continuous adjustment is performed to maintain the wavelength stable at the target laser wavelength or within its allowable error range.

By employing the negative feedback regulation device, the present invention can monitor and adjust the laser wavelength in real time, significantly improving the precision of wavelength regulation. The calibration data table ensures the correspondence between the operating voltage of the galvanometer driver and the actual laser wavelength, thereby achieving precise control of the output wavelength.

It should be noted that in the embodiments of the present invention, all directional indications (such as up, down, left, right, front, back . . . ) are only used to explain the relative positional relationships, movement states, etc., between various components under a specific posture (as shown in the drawings). If this specific posture changes, the directional indication will change accordingly.

Furthermore, in the present invention, terms such as “first”, “second”, “a/an”, etc., are used for descriptive purposes only and should not be understood as indicating or implying relative importance or the quantity of the technical features indicated. Accordingly, features defined as “first” or “second” may explicitly or implicitly include at least one of said features. In the description of the present invention, “a plurality” means at least two, such as two, three, etc., unless otherwise and specifically clearly defined.

In the present invention, unless otherwise explicitly specified and defined, terms such as “connected”, “fixed”, etc., should be understood in a broad sense. For example, “fixed” may refer to a rigid connection or a detachable connection; it can be a mechanical connection or an electrical connection; it can be a direct connection or an indirect connection through an intermediate medium, it may refer to communication within two components or the interaction relationship between two components, unless otherwise explicitly defined. For a person skilled in the art, the specific meaning of these terms in the present invention can be understood according to the actual situation.

Furthermore, the technical solutions between the various embodiments of the present invention can be combined with each other, provided that such combinations can be realized by a person skilled in the art. When the combination of technical solutions is mutually contradictory or cannot be achieved, it should be considered that such a combination of technical solutions does not exist and is not within the scope of protection claimed by the present invention.

1. A closed-loop output-wavelength tuning method, performed by a system comprising a negative feedback regulation device and an external cavity broadband tunable laser;
wherein the external cavity broadband tunable laser comprises: a galvanometric scanner, a galvanometer driver configured to control an angle of the galvanometric scanner, and a resonant cavity configured to output a laser beam at a wavelength that changes in the angle of the galvanometric scanner;
wherein the negative feedback regulation device comprises: a visible light laser and a one-dimensional position detector; the visible light laser is configured to emit a different laser beam, which is reflected by the galvanometric scanner and then directed to the one-dimensional position detector;
wherein the closed-loop output-wavelength tuning method comprises:
adjusting the operating voltage of the galvanometer driver to vary the angle of the galvanometric scanner, thereby altering a position of a light spot formed after reflection of a laser beam emitted by the visible light laser, causing the light spot to sequentially pass through a plurality of preset position points on a photosensitive area of the one-dimensional position detector; as the light spot passes each preset position point, simultaneously recording the position point as the light spot's position, together with a corresponding operating voltage of the galvanometer driver, and a corresponding laser wavelength output by the resonant cavity, thereby generating calibration data corresponding to the position point;
setting a target laser wavelength to be output by the resonant cavity, retrieving a laser wavelength matching the target wavelength from the calibration data, and based on the matched laser wavelength, obtaining a corresponding operating voltage of the galvanometer driver;
activating the external cavity broadband tunable laser to emit a first beam, and starting the galvanometer driver with the corresponding operating voltage to rotate the galvanometric scanner, while simultaneously operating the negative-feedback regulation device to emit a second laser beam;
iteratively performing following steps to make a laser wavelength output by the resonant cavity reach the target laser wavelength: during the operation of the external cavity broadband tunable laser, calculating a real-time spot position corresponding to the second laser beam on the one-dimensional position detector through the negative feedback regulation device, and matching the real-time spot position with spot positions in the calibration data to obtain a corresponding laser wavelength; by comparing the corresponding laser wavelength with the target laser wavelength, determining a voltage adjustment value; and using the voltage adjustment value to increase or decrease the corresponding operating voltage of the galvanometer driver.

2. The closed-loop output-wavelength tuning method according to claim 1, wherein:
the negative feedback regulation device further comprises: a controller;
the method further comprises generating, by the one-dimensional position detector, a photocurrent at an irradiated location when the laser spot impinges on the photosensitive area, and collecting a current signal through electrodes on both ends of the one-dimensional position detector;
calculating the real-time spot position corresponding to the second laser beam on the one-dimensional position detector through the negative feedback regulation device comprises calculating, by the controller, the real-time spot position based on the collected current signal; and
the position of the light spot is a vertical distance between the light spot and the center line of the photosensitive area.

3. The closed-loop output-wavelength tuning method according to claim 2, wherein the external cavity broadband tunable laser further comprises: a blazed grating
configured to reflect light of specific wavelengths back into the resonant cavity via diffraction;
wherein the resonant cavity comprises a first collimating lens, a laser gain chip, and a second collimating lens;
wherein the method further comprises:
reflecting, by the galvanometric scanner, incident light emitted by the laser gain chip through the first collimating lens onto the blazed grating;
diffracting, by the blazed grating, the incident light according to the incident light's wavelength;
reflecting, by the galvanometric scanner, the diffracted incident light back through the first collimating lens into the laser gain chip; after wavelength selection by the blazed grating, light of a specific wavelength undergoes gain amplification within the resonant cavity, and when the light's intensity exceeds a lasing threshold for the specific wavelength, outputting a laser of the specific wavelength through the second collimating lens.

4. The closed-loop output-wavelength tuning method negative according to claim 3, wherein a laser beam path emitted by the visible light laser and a laser beam path emitted by the laser gain chip do not interfere with each other.

5. The closed-loop output-wavelength tuning method according to claim 4, wherein retrieving the laser wavelength matching the target wavelength from the calibration data comprises: searching the calibration data for a laser wavelength matching the target wavelength; if a matching laser wavelength exists, obtaining a corresponding operating voltage of the galvanometer driver; and if no matching laser wavelength exists, performing interpolation on the calibration data to obtain calibration data corresponding to the target wavelength;
matching the real-time spot position with the spot positions in the calibration data comprises: if a matching spot position exists, obtaining the laser wavelength corresponding to that spot position; and if no matching spot position exists, performing interpolation on the calibration data to obtain calibration data corresponding to the real-time spot position, and acquiring the laser wavelength contained in the calibration data.

6. The closed-loop output-wavelength tuning method according to claim 5, wherein performing the interpolation of the calibration data to obtain the calibration data matching the target laser wavelength comprises:
finding two laser wavelengths in the calibration data closest to the target laser wavelength and their corresponding calibration data;
calculating calibration data matching the target laser wavelength based on the two wavelengths according to:
$$V = {V}_{1} + \frac{( {V}_{2} - {V}_{1} ) \times ( λ - {λ}_{1} )}{( {λ}_{2} - {λ}_{1} )} ;$$
$$x = {x}_{1} + \frac{( {x}_{2} - {x}_{1} ) \times ( λ - {λ}_{1} )}{( {λ}_{2} - {λ}_{1} )} ;$$
wherein, V₁, V₂ represent operating voltages of the galvanometer driver in the closest calibration data; λ₁, λ₂ represent laser wavelengths corresponding to V₁, V₂ respectively; x₁, x₂ represent light spot's positions corresponding to V₁, V₂ respectively; λ represents the target laser wavelength; wherein: V₁<V<V₂; V, x represent the operating voltage of the galvanometer driver and light spot's position matching the target laser wavelength, respectively.

7. The closed-loop output-wavelength tuning method according to claim 5, further comprising: calculating, by the controller, the real-time spot position based on the collected current signal, according to:
$${I}_{L} = \frac{1}{2} ( 1 + \frac{2}{L} x ) {I}_{0} ;$$
$${I}_{R} = \frac{1}{2} ( 1 - \frac{2}{L} x ) {I}_{0}$$
$$x = \frac{Δ}{2 \sum } L ; Δ = {I}_{L} - {I}_{R} ; \sum = {I}_{L} + {I}_{R} ;$$
wherein, I₀ is a magnitude of photocurrent produced when the laser spot impinges on the photosensitive area; I_{L} and I_{R} represent the photocurrents received by the first and second electrodes of the one-dimensional position detector, respectively; L represents a length of the photosensitive area of the one-dimensional position detector; x represents the calculated real-time light-spot position.

8. A closed-loop output-wavelength tuning system, comprising a negative feedback regulation device and an external cavity broadband tunable laser;
wherein the external cavity broadband tunable laser comprises: a galvanometric scanner, a galvanometer driver configured to control an angle of the galvanometric scanner, and a resonant cavity configured to output a first laser beam at a wavelength that changes in the angle of the galvanometric scanner;
wherein the negative feedback regulation device comprises: a visible light laser and a one-dimensional position detector;
wherein the visible light laser is configured to emit a second laser beam;
wherein the galvanometric scanner is configured to reflect the second laser beam onto the one-dimensional position detector, forming a light spot on a photosensitive area of the one-dimensional position detector:
wherein the galvanometer driver is configured to vary the angle of the galvanometric scanner, causing the light spot to sequentially pass through a plurality of preset position points on the photosensitive area of the one-dimensional position detector;
wherein the system is configured to, as the light spot passes each preset position point, simultaneously record the position point as the light spot's position, together with a corresponding operating voltage of the galvanometer driver, and a corresponding laser wavelength output by the resonant cavity as calibration data;
wherein the system is configured to retrieve a laser wavelength matching a target wavelength from the calibration data, and based on the matched laser wavelength, obtain a corresponding operating voltage of the galvanometer driver;
wherein the galvanometer driver is configured to rotate the galvanometric scanner at the corresponding operating voltage, changing the wavelength of the first laser beam;
wherein the system is configured to iteratively perform following steps until the wavelength of the first laser beam reaches the target laser wavelength: calculating a real-time spot position corresponding to the second laser beam on the one-dimensional position detector through the negative feedback regulation device, and matching the real-time spot position with spot positions in the calibration data to obtain a corresponding laser wavelength; by comparing the corresponding laser wavelength with the target laser wavelength, determining a voltage adjustment value; and
using the voltage adjustment value to increase or decrease the corresponding operating voltage of the galvanometer drive.

9. The closed-loop output-wavelength tuning system according to claim 8, wherein:
the negative feedback regulation device further comprises: a controller;
the one-dimensional position detector is configured to generate a photocurrent at the irradiated location when the laser spot impinges on the photosensitive area, and collect a current signal is through electrodes on both ends of the one-dimensional position detector;
the controller is configured to calculate the real-time spot position based on the collected current signal;
the position of the light spot refers to the vertical distance between the light spot and the center line of the photosensitive area.

10. The closed-loop output-wavelength tuning system according to claim 9, wherein the external cavity broadband tunable laser further comprises:
a blazed grating configured to reflect light of specific wavelengths back into the resonant cavity via diffraction;
wherein the resonant cavity comprises a first collimating lens, a laser gain chip, and a second collimating lens;
wherein the galvanometric scanner is configured to reflect incident light emitted by the laser gain chip through the first collimating lens onto the blazed grating;
wherein the blazed grating is configured to diffract the incident light according to the incident light's wavelength;
wherein the galvanometric scanner is configured to reflect the diffracted incident light back through the first collimating lens into the laser gain chip;
wherein the system is configured to, after wavelength selection by the blazed grating, light of the specific wavelength undergoes gain amplification within the resonant cavity, and when its intensity exceeds the lasing threshold for the specific wavelength, output a laser of the specific wavelength through the second collimating lens.

11. The closed-loop output-wavelength tuning system according to claim 10, wherein a laser beam path emitted by the visible light laser and a laser beam path emitted by the laser gain chip do not interfere with each other.

12. The closed-loop output-wavelength tuning system according to claim 11, wherein the system is configured to:
search the calibration data for a laser wavelength matching the target wavelength; if a matching laser wavelength exists, obtain a corresponding operating voltage of the galvanometer driver; and
if no matching laser wavelength exists, perform interpolation on the calibration data to obtain calibration data corresponding to the target wavelength;
if a matching spot position exists, obtain the laser wavelength corresponding to that spot position;
and if no matching spot position exists, perform interpolation on the calibration data to obtain calibration data corresponding to the real-time spot position, and acquire the laser wavelength contained in the calibration data.

13. The closed-loop output-wavelength tuning system according to claim 12, wherein the system is configured to:
find two laser wavelengths in the calibration data closest to the target laser wavelength and their corresponding calibration data;
calculate calibration data matching the target laser wavelength based on the two wavelengths according to:
$$V = {V}_{1} + \frac{( {V}_{2} - {V}_{1} ) \times ( λ - {λ}_{1} )}{( {λ}_{2} - {λ}_{1} )} ;$$
$$x = {x}_{1} + \frac{( {x}_{2} - {x}_{1} ) \times ( λ - {λ}_{1} )}{( {λ}_{2} - {λ}_{1} )} ;$$
Wherein, V₁, V₂ represent operating voltages of the galvanometer driver in the closest calibration data; λ₁, λ₂ represent laser wavelengths corresponding to V₁, V₂ respectively; x₁, x₂ represent light spot's positions corresponding to V₁, V₂ respectively; λ represents the target laser wavelength; wherein: V₁<V<V₂; V, x represent the operating voltage of the galvanometer driver and light spot's position matching the target laser wavelength, respectively.

14. The closed-loop output-wavelength tuning system according to claim 12, wherein the controller is configured to calculate the real-time spot position based on the collected current signal, according to:
$${I}_{L} = \frac{1}{2} ( 1 + \frac{2}{L} x ) {I}_{0} ;$$
$${I}_{R} = \frac{1}{2} ( 1 - \frac{2}{L} x ) {I}_{0}$$
$$x = \frac{Δ}{2 \sum } L ; Δ = {I}_{L} - {I}_{R} ; \sum = {I}_{L} + {I}_{R} ;$$
wherein, I₀ is a magnitude of photocurrent produced when the laser spot impinges on the photosensitive area; I_{L} and I_{R} represent the photocurrents received by the first and second electrodes of the one-dimensional position detector, respectively; L represents a length of the photosensitive area of the one-dimensional position detector; x represents the calculated real-time spot position.
